(19) United States
(12) Patent Application Publication
(10) Pub. No.: US 2024/0051129 A1
(43) Pub. Date: Feb. 15, 2024

(54) ROBOT AND TEACHING METHOD

(71) Applicant: KAWASAKI JUKOGYO KABUSHIKI KAISHA, Kobe-shi, Hyogo (JP)

(72) Inventors: Kazuma KANEZAKI, Kobe-shi (JP); Atsushi NAKAYA, Kobe-shi (JP); Junichi MATSUOKA, Kobe-shi (JP)

(73) Assignee: KAWASAKI JUKOGYO KABUSHIKI KAISHA, Kobe-shi, Hyogo (JP)

(21) Appl. No.: 18/265,768

(22) PCT Filed: Nov. 18, 2021
(86) PCT No.: PCT/JP2021/042423

§ 371 Date: Jun. 7, 2023

(30) Foreign Application Priority Data
Dec. 9, 2020 (JP) 2020-203798

(51) Int. Cl. B25J 9/16; B25J 9/04; B25J 13/08; B25J 11/00

(52) U.S. Cl. CPC B25J 9/163; B25J 9/042; B25J 13/08; B25J 11/0095

(57) ABSTRACT

A horizontally articulated robot includes a manipulator, a hand, and a teaching member. The hand is connected to the manipulator. The hand is capable of holding a substrate. The teaching member is connected to the manipulator. The teaching member is not used for transferring a substrate.

### TECHNICAL FIELD

The present disclosure relates to teaching to a horizontally articulated robot.

### BACKGROUND ART

PTL 1 discloses a teaching device for positioning (teaching) a wafer handling robot. The teaching device includes a substrate and a fitting portion. The fitting portion is fitted to an end-effector provided by the wafer handling robot. When the end-effector is positioned in contact with the substrate, a position of an upper surface of the end-effector matches a lower surface of the wafer. Once the end-effector is fitted to the fitting portion, teaching of the end-effector, arms, and rotary axes of the wafer handling robot is performed.

### PRIOR-ART DOCUMENTS

### Patent Documents

PTL 1: JP 4601130 B2

### SUMMARY OF THE INVENTION

### Problems to be Solved by the Invention

In the configuration of the above PTL 1, the hand, which is the end-effector, is directly used for teaching. Therefore, the hand is easily subjected to load, which may cause deformation or damage to the hand during teaching. Since the hand that transfers the wafer is required to be lightweight and compact, it was also difficult to improve the mechanical strength of the hand.

The present disclosure has been made in view of the above circumstances, and its purpose is to provide a robot with good durability regarding teaching operation.

### Means for Solving the Problems

The problem to be solved by the present disclosure is as described above, and next, means for solving the problem and effects thereof will be described below.

According to a first aspect of the present disclosure, a robot having the following configuration is provided. That is, a horizontally articulated robot includes a manipulator, a hand, and a teaching member. The hand is rotatably connected to the manipulator around a vertical axis. The hand is capable of holding a substrate. The teaching member is rotatably connected to the manipulator around a vertical axis. The teaching member is not used for transferring a substrate.

According to a second aspect of the present disclosure, provided is a following teaching method for a horizontally articulated robot that holds and transfers a substrate by a hand connected to a manipulator. That is, in this teaching method, teaching is performed using a teaching member connected to the manipulator that is not used for transferring a substrate.

This enables automatic teaching to the robot using the teaching member provided on the robot side. Since teaching is performed using the teaching member that is a member other than the hand, damage to the hand can be prevented.

### Effects of the Invention

According to the present disclosure, a robot with good durability regarding teaching operation is provided.

### BRIEF DESCRIPTION OF THE DRAWINGS

FIG. 1 is a perspective diagram showing an overall configuration of a robot system according to one embodiment of the present disclosure.

FIG. 2 is a perspective diagram showing a configuration of a robot.

FIG. 3 is a block diagram showing a configuration of a part of the robot system.

FIG. 4 is a perspective diagram showing a teaching member being set on a teaching table.

FIG. 5 is a block diagram showing servo control of a motor that rotates and drives the teaching member.

### EMBODIMENT FOR CARRYING OUT THE INVENTION

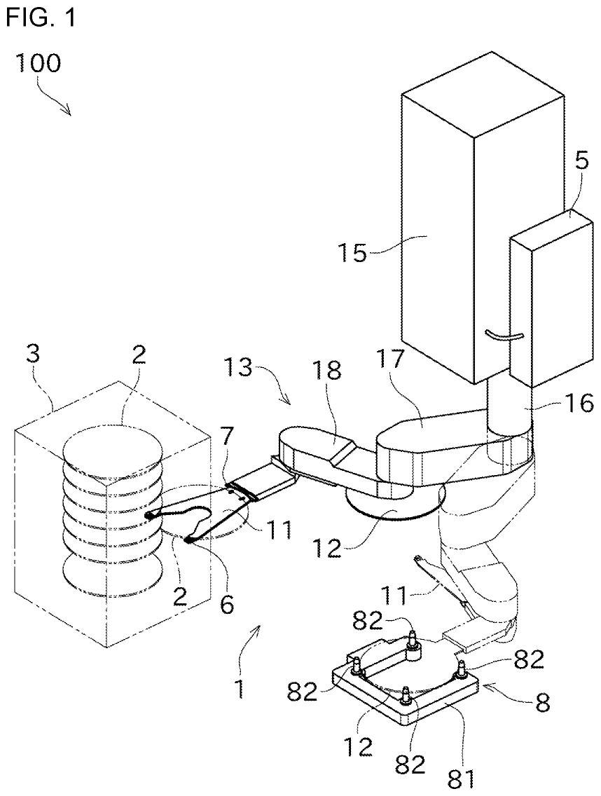

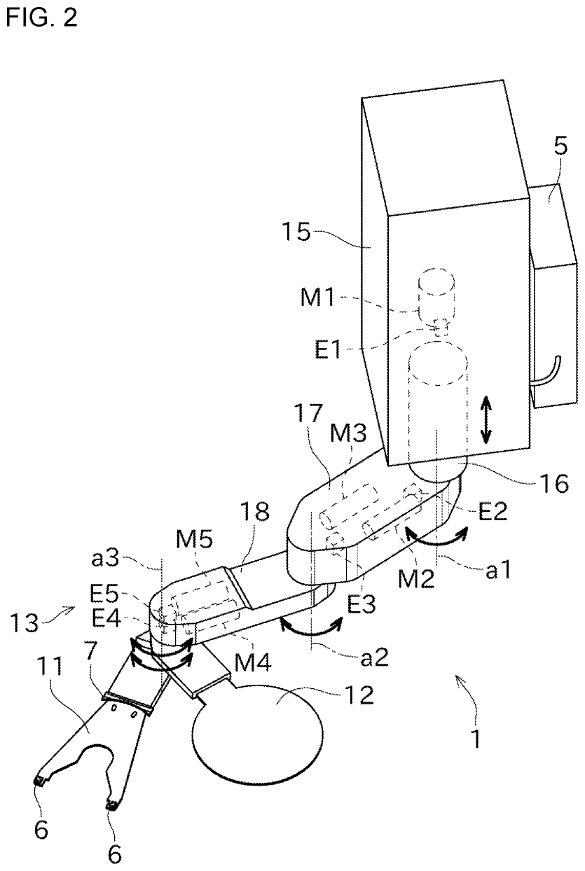

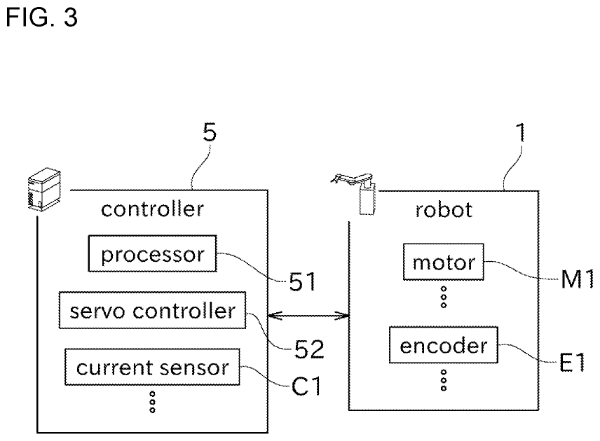

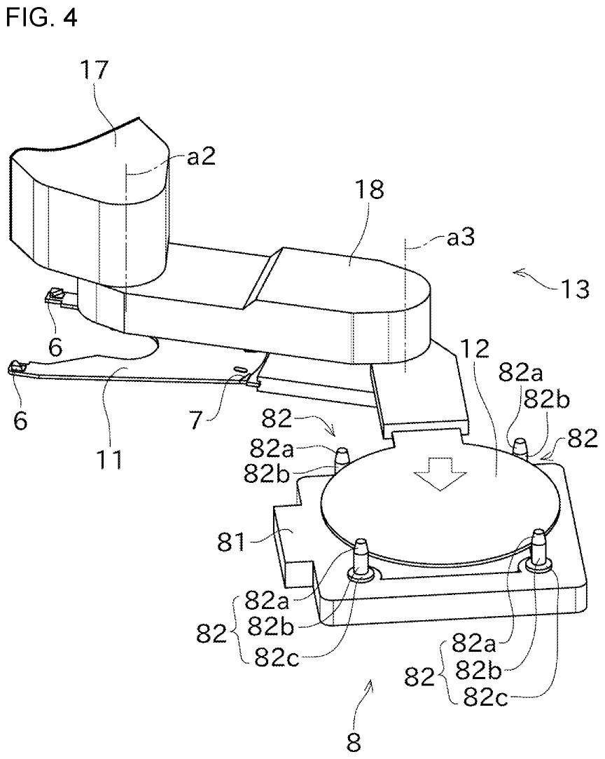

Next, the disclosed embodiments will be described with reference to the drawings. FIG. 1 is a perspective diagram showing a configuration of a robot system 100 according to one embodiment of the present disclosure. FIG. 2 is a perspective diagram showing a configuration of a robot 1. FIG. 3 is a block diagram showing a configuration of a part of the robot system 100. FIG. 4 is a perspective diagram showing a teaching member 12 being set on a teaching table 8.

The robot system 100 shown in FIG. 1 is a system that allows the robot 1 to perform work in a clean room or other work space.

The robot system 100 includes a robot 1, a controller 5, and a teaching table 8.

The robot 1 functions, for example, as a wafer transfer robot that transfers the wafer (substrate) 2 stored in a storage container 3. In this embodiment, the robot 1 is realized by a SCARA (Selective Compliance Assembly Robot Arm) type horizontal articulated robot. SCARA is an abbreviation for Selective Compliance Assembly Robot Arm.

As shown in FIG. 2, the robot 1 includes a hand (holder) 11, a teaching member 12, and a manipulator 13.

The hand 11 is a type of end-effector and is approximately V-shaped or U-shaped in a plan view. The hand 11 is supported at a tip of the manipulator 13 (specifically, a second link 18 described below). The hand 11 can rotate around a third axis a3 extending in a vertical direction with respect to the second link 18.

The hand 11 is configured as an edge-grip hand. An edge guide 6 is provided at each of the bifurcated tips in the hand 11. A presser 7 is provided in a vicinity of a wrist of the hand 11. The presser 7 is moved toward the tip of the hand 11 by an actuator (for example, a pneumatic cylinder), not shown in the figure, built in the wrist of the hand 11.

By displacing the presser 7 toward the tip end with the wafer 2 on an upper side of the hand 11, the wafer 2 can be held between the edge guide 6 and the presser 7.

The teaching member 12 is plate-shaped. The teaching member 12 is arranged with its thickness direction facing in the vertical direction. The teaching member 12 is supported at the tip of the manipulator 13 (the second link 18). The teaching member 12 can rotate about the third axis a3 described above with respect to the second link 18.

In the present embodiment, the teaching member 12 is disc-shaped. However, the shape of the teaching member 12 in a plan view is arbitrary. An outer peripheral surface of the teaching member 12 is contactable with teaching pins 82 provided by the teaching table 8, as shown in a chain line in FIG. 1. The detailed configuration of the teaching table 8 will be described below. In the present embodiment, the diameter of the disc-shaped portion of the teaching member 12 is equal to the diameter of the wafer 2 to be transferred. However, the diameter of the disc-shaped portion of the teaching member 12 may be larger or smaller than the diameter of the wafer 2.

The teaching member 12 is not intended to transfer the wafer 2. Therefore, the edge guide 6 and the presser 7, etc. are not provided in the teaching member 12.

The manipulator 13 mainly includes a base 15, an elevation shaft 16, and a plurality of links (here, a first link 17 and a second link 18).

The base 15 is fixed, for example, to a ceiling surface composing the clean room. The base 15 functions as a base member supporting the elevation shaft 16.

The elevation shaft 16 moves in the vertical direction with respect to the base 15. This elevation allows, a height of the first link 17, the second link 18, the hand 11 and the teaching member 12 to be changed.

The base 15 is provided with a motor M1 and an encoder E1. The motor M1 drives the elevation shaft 16 via, for example, a screw mechanism, which is not shown in the figure. The encoder E1 detects a vertical position of the elevation shaft 16.

The first link 17 is supported at a lower part of the elevation shaft 16. The first link 17 rotates about a first axis a1 extending in a vertical direction with respect to the elevation shaft 16. This allows a posture of the first link 17 to be changed in a horizontal plane.

The first link 17 is provided with a motor M2 and an encoder E2. The motor M2 drives the first link 17 to rotate with respect to the elevation shaft 16. The encoder E2 detects an angle of the first link 17 with respect to the elevation shaft 16.

The second link 18 is supported at a tip of the first link 17. The second link 18 rotates about a second axis a2 extending in the vertical direction with respect to the first link 17. This allows a posture of the second link 18 to be changed in the horizontal plane.

The first link 17 is provided with a motor M3 and an encoder E3. The motor M3 drives the second link 18 to rotate with respect to the first link 17. The encoder E3 detects an angle of the second link 18 with respect to the first link 17.

The second link 18 is provided with a motor M4 and an encoder E4. The motor M4 drives the hand 11 to rotate with respect to the second link 18. The encoder E4 detects an angle of the hand 11 with respect to the second link 18.

The second link 18 is provided with a motor M5 and an encoder E5. The motor M5 drives the teaching member 12 to rotate with respect to the second link 18. The encoder E5 detects an angle of the teaching member 12 with respect to the second link 18.

The motors M1-M5 are actuators that drive various parts of the robot 1. Each of the motors M1-M5 is configured as a servo motors, which is a type of electric motor. By driving the motors M1-M5, positions and postures of the hand 11 and the teaching member 12 can be changed in various ways. As shown in FIG. 3, the motors M1-M5 are electrically connected to the controller 5. Each of the motors M1-M5 is driven to reflect command values input from the controller 5.

The controller 5 is provided with a drive circuit for driving the motors M1-M5. The drive circuit is connected to the motors M1-M5 of the robot 1 through an electrical cable, which is not shown in the figure. The drive circuit is provided with current sensors C1-C5. The current sensors C1-C5 can detect the current values of the motors M1-M5.

The encoder E1 is a sensor that detects a position. The encoders E2-E5 are sensors that detect angles. Based on detection results of the encoders E1-E5, the positions and the postures of the hand 11 and the teaching member 12 can be detected. The encoders E1-E5 are electrically connected to the controller 5. Each of the encoders E1-E5 outputs the detection result to the controller 5.

The controller 5 controls the motors M1-M5 by outputting command values according to a predetermined operation program or a movement command input by a user, to move the hand 11 and the teaching member 12 to predetermined positions.

The controller 5 includes a processor 51 and a servo controller 52, as shown in FIG. 3. The processor 51 performs processing in accordance with the program. The servo controller 52 performs necessary processing for servo control of the motors M1-M5.

The controller 5 is configured as a known computer including a CPU, a ROM, a RAM, auxiliary storage, and the like. The auxiliary storage is configured as an HDD, an SSD, etc., for example. The auxiliary storage stores a robot control program and a program for realizing the teaching method of the present disclosure. These hardware and software work cooperatively, so that the controller 5 can be operated as the processor 51 and the servo controller 52, etc.

The teaching table 8 includes a base member 81 and teaching pins (positioning members) 82, as shown in FIG. 4.

The base member 81 is fixed to an installation surface for the robot 1. The base member 81 is fixed to an upper surface of a stage, not shown, that is located around the robot 1.

Four teaching pins 82 are fixed to an upper surface of the base member 81. Each teaching pin 82 is provided to protrude upward from the base member 81. The shapes of the four teaching pins 82 are identical to each other. In a plan view, the four teaching pins 82 are arranged to be at an equal distance from a predetermined reference point. The reference point corresponds to a teaching position in the plan view. A disc portion of the teaching member 12 can be inserted from above into the space surrounded by the four teaching pins 82.

All four teaching pins 82 each include a tip taper 82a, a cylinder 82b, and a root taper 82c.

The tip taper 82a is located at an upper end of the teaching pin 82. The tip taper 82a is cone-shaped, whose diameter increases downward. A lower end of the tip taper 82a is connected to the cylinder 82b. The tip tapers 82a allow the teaching member 12 inserted from above to be guided to enter among the cylinders 82b of the four teaching pins 82.

The cylinder 82b is located in the middle of the teaching pin 82 in the vertical direction. The four teaching pins 82 are located so that when the teaching member 12 is inserted to a height corresponding to the cylinders 82b, there are small gaps between the outer peripheral surface of the teaching member 12 and the outer peripheral surfaces of the cylinders 82b.

The root taper 82c is located at a lower end of the teaching pin 82. The root taper 82c is cone-shaped, whose diameter increases downward. An upper end of the root taper 82c is connected to the cylinder 82b. A height of a boundary between the cylinder 82b and the root taper 82c corresponds to the teaching position in the vertical direction.

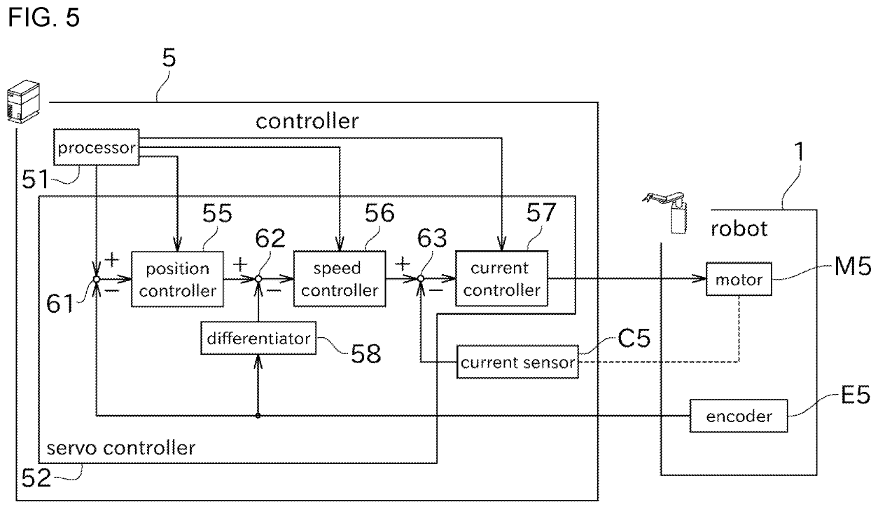

Next, the servo controller 52 will be described in detail. FIG. 5 schematically shows the control system of the robot 1, taking as an example the motor M5 that rotates the teaching member 12 with respect to the second link 18.

The servo controller 52 includes a position controller 55, a speed controller 56, a current controller 57, and a differentiator 58. Furthermore, the servo controller 52 includes subtractors 61, 62, 63.

The processer 51 provided by the controller 5 generates a command value for the angular position and outputs the command value to the subtractor 61. A detection value of the angular position detected by the encoder E5 is input to the subtractor 61. The subtractor 61 calculates a deviation of the angular position and outputs the result to the position controller 55.

The position controller 55 generates a speed command value from the angle deviation input from the subtractor 61 using a process based on a predetermined transfer function or proportional coefficient. The position controller 55 outputs the generated speed command value to the subtractor 62. A speed value acquired by differentiating the angular position of the encoder E5 by the differentiator 58 is input to the subtractor 62. The subtractor 62 calculates the speed deviation and outputs the result to the speed controller 56.

The speed controller 56 generates a current command value from the speed deviation input from the subtractor 62 using an arithmetic process based on a predetermined transfer function or proportional coefficient. The speed controller 56 outputs the generated current command value to the subtractor 63. The current value of the motor M5, detected by the current sensor C5, is input to the subtractor 63. The subtractor 63 calculates a current deviation and outputs the result to the current controller 57.

The current controller 57 controls the current value output to the motor M5 based on the current deviation input from the subtractor 63.

The processor 51 outputs a signal instructing at least one of the position controller 55, the speed controller 56, and the current controller 57 provided by the servo controller 52 to switch gain. This causes the gain to be substantially zero in at least one of the position controller 55, the speed controller 56, and the current controller 57. In other words, at least one of the position loop gain, the speed loop gain, and the current loop gain is substantially zero.

When the gain is zero or close to zero, the rotation angle of the motor M5 is free to be changed by external force applied to the teaching member 12 (for example, reaction force when the teaching member 12 contacts the teaching pins 82).

Although the motor M5 is used as an example above, other motors M1-M4 can be similarly set to a state where the servo control gain is substantially zero, so that the rotation angle of the motors M1-M4 can be freely changed.

When performing automatic teaching of the robot 1 in the present embodiment, the controller 5 controls the motors M1-M5 so that the teaching member 12 of the robot 1 is positioned almost directly above the teaching table 8. At this time, the hand 11 should be in a posture that does not substantially overlap the teaching member 12.

The processor 51 of the controller 5 then sets the servo control gain to substantially zero with respect to the motors M1-M3, M5. In this state, the processor 51 drives the motor M1 to lower the teaching member 12 together with the elevation shaft 16.

Due to tolerance of the robot 1 or other factors, the center of the teaching member 12 may not be aligned with the center of the teaching table 8. In this case, the outer peripheral surface of the teaching member 12 moving downward contacts and pushes against the tip taper 82a of any of the teaching pins 82. Since the servo control gain is substantially zero, the posture of the teaching member 12, the first link 17, and the second link 18 changes freely as the teaching member 12 is pushed.

As the teaching member 12 is lowered, the teaching member 12 eventually rests on the root tapers 82c of the teaching pins 82. As a result, the elevation shaft 16 will no longer lowered even when the motor M1 is driven. The position of the teaching member 12 at this time is the teaching position. The processor 51 of the controller 5 stores the detection results of the encoders E1-E3, E5 at this time. As described above, automatic teaching using the teaching member 12 is realized.

There are various ways to make the rotation angle of the motors M1-M5 freely changeable. Instead of lowering the gain, the processor 51 may set any of the position deviation, the speed deviation, and the current deviation to zero or close to zero. The processor 51 may set the current value output from the current controller 57 to the motors M1-M5 to zero or close to zero. The current command value output from the speed controller 56 may be zero or close to zero.

In the present embodiment, the teaching member 12 is provided at the robot 1 side separately from the hand 11 used to transfer the wafer 2. This teaching member 12 is not used to transfer the wafer 2. Therefore, it is easy to configure the teaching member 12 so that it is simple and has good mechanical strength compared to the hand 11, which requires a precise mechanism such as the presser 7. Thus, it can be configured to have resistance to damage even if an external force is applied during teaching, and realizes a configuration having excellent durability.

For example, when transferring semiconductor wafers 2, the robot 1 may be located in a closed space in order to work in a highly clean environment. In this configuration, the teaching table 8 is not visible from the outside, and visual teaching using a known teach pendant is difficult. However, according to the present embodiment, teaching is performed without problems even when the robot 1 is placed in the closed space because the teaching is automatically performed by the teaching member 12 provided by the robot 1.

When processing the wafers 2 to be wetted with water or other liquids, it is often difficult to locate sensors, which are electrical components, in the vicinity of the teaching member 12. In the present embodiment, teaching is realized using the encoders E1-E3, E5 that the robot 1 normally includes for control. Therefore, the configuration of the present embodiment is particularly preferable for application in wet environments.

When the teaching member 12 is not in use, the controller 5 controls the posture of the teaching member 12 so that it is in a 180-degree folded posture with respect to the second link 18, as shown by a solid line in FIG. 1. The 180-degree folded posture can also be described as a posture aligned with the second link 18. By controlling the posture of the teaching member 12 so that the teaching member 12 partially overlaps the second link 18 in a plan view, the teaching member 12 does not interfere with the transfer of the wafer 2 and is less likely to interfere with surrounding members.

When the teaching member 12 is used, the controller 5 controls the posture of the hand 11 so that the hand 11 is 180-degree folded with respect to the second link 18, as shown in FIG. 4, etc. By controlling the posture of the hand 11 so that the hand 11 partially overlaps the second link 18 in a plan view, the hand 11 does not interfere with the teaching to the robot 1.

As described above, the horizontally articulated robot 1 of the present embodiment includes the manipulator 13, the hand 11, and the teaching member 12. The hand 11 is rotatably connected to the manipulator 13 around the third axis a3 in the vertical direction. The hand 11 is capable of holding the wafer 2. The teaching member 12 is rotatably connected to the manipulator 13 around the third axis a3 in the vertical direction. The teaching member 12 is not used for transferring a wafer 2.

This enables automatic teaching to the robot 1 using the teaching member 12 provided on the robot 1 side. Since the teaching is performed using the teaching member 12, which is a different member from the hand 11, damage to the hand 11 can be prevented.

In the robot 1 of the present embodiment, the teaching member 12 is used for teaching to the robot 1.

This eliminates the need to attach a jig to the robot 1 for teaching to the robot 1. Thus, this simplifies the operation of the robot 1 for teaching.

In the robot 1 of the present embodiment, the manipulator 13 includes the links 17, 18 and the encoders E2, E3, E5. The encoders E2, E3, E5 detect the posture of the links 17, 18 and the teaching member 12. Teaching to the robot 1 is performed based on the detection results of the encoders E2, E3, E5 when the teaching member 12 contacts the teaching pins 82 fixedly installed with respect to the installation surface for the robot 1.

This reduces the cost since no special additional electrical configuration, such as sensors, is required.

In the robot 1 of the present embodiment, when the wafer 2 is transferred by the hand 11, the teaching member 12 is in a posture wherein the teaching member 12 is at least partially overlapped with the manipulator 13 in a plan view.

This allows the teaching member 12 not to interfere when transferring the wafer 2.

In the robot 1 of the present embodiment, when the wafer 2 is transferred by the hand 11, in a plan view, the teaching member 12 maintains the posture along the link 18 that is located at the most apical side of the manipulator 13.

This makes the teaching member 12 less likely to interfere with its surroundings.

In the robot 1 of the present embodiment, when teaching to the robot 1 is performed by the teaching member 12, the hand 11 is in the posture that overlaps the manipulator 13 at least partially in a plan view.

This prevents the hand 11 from interfering when teaching.

In the robot 1 of the present embodiment, the hand 11 is rotatably connected to the tip of the manipulator 13 around the third axis a3 directed in the vertical direction. The teaching member 12 is rotatably connected to the tip of the manipulator 13 about the third axis a3 coaxially with the axis about which the hand 11 is rotatable.

Since the teaching member 12 and the hand 11 are coaxially arranged, teaching by the teaching member 12 ensures good accuracy of movement of the hand 11.

While suitable embodiments of the present disclosure have been described above, the above configuration can be modified, for example, as follows.

Only teaching the position in the plan view may be performed, and teaching the position in the vertical direction may be omitted. In this case, the root taper 82c can be omitted in the teaching pin 82.

In teaching, it is not necessary to use the teaching member 12 being pressed in contact with the teaching pins 82. For example, a non-contact type sensor (for example, an optical sensor) can be located at an appropriate position, and the position at which the sensor detects the teaching member 12 can be used as the teaching position.

Instead of being connected via the third axis a3, the teaching member 12 can be configured to be connected via the second axis a2 or the first axis a1, for example.

The teaching member 12 need not be disc-shaped. For example, the teaching member 12 can be formed in a flat oval shape, which is an elongated rectangle deformed so that each of its two opposing sides projects outward in an arc. The teaching member 12 can also be configured as a polygon, such as a triangular, a quadrilateral, a hexagonal, etc.

An axis hole can be formed through the teaching member 12. In this case, the teaching pin 82 can be configured to contact the inner circumference of the axis hole. If the axis hole is formed as a circular hole, instead of the teaching pin 82, a conical positioning member that can be inserted into the axis hole can be provided on the teaching table 8.

The number of the teaching pins 82 is not limited to four, but can be three, for example.

In the above embodiment, the teaching member 12 is arranged above the hand 11 and the second link 18 is arranged above the teaching member 12. In other words, in the direction of the third axis a3, the teaching member 12 is closer to the second link 18 than the hand 11. However, the teaching member 12 may be located below the hand 11.

Instead of a configuration in which the base 15 is installed on the ceiling (i.e., ceiling-mount type), the robot 1 can be configured so that the base 15 is installed on a floor.

The hand 11 can also be configured to be flip-operable. Even in this case, the teaching member 12 need not have a flip operation function. Since the teaching member 12 does not have the flip operation function, a simple configuration of the teaching member 12 can be realized.

The present invention can also be applied to a robot for transferring a substrate other than the wafer 2 (for example, a glass plate).

The functionality of the elements disclosed herein may be implemented using circuitry or processing circuitry which includes general purpose processors, special purpose processors, integrated circuits, ASICs (“Application Specific Integrated Circuits”), conventional circuitry and/or combinations thereof which are configured or programmed to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein or otherwise known which is programmed or configured to carry out the recited functionality. When the hardware is a processor which may be considered a type of circuitry, the circuitry, means, or units are a combination of hardware and software, the software being used to configure the hardware and/or processor.

1. A horizontally articulated robot, comprising:
a manipulator;
a hand rotatably connected to the manipulator around a vertical axis and capable of holding a substrate; and
a teaching member rotatably connected to the manipulator around a vertical axis and is not used for transferring a substrate.

2. The robot according to claim 1, wherein
the teaching member is used for teaching to the robot.

3. The robot according to claim 2, wherein
the manipulator comprises:
a link; and
a sensor that detects a posture of at least one of the link and the teaching member, and
teaching to the robot is performed based on a detection result of the sensor when the teaching member contacts a positioning member fixedly installed with respect to an installation surface for the robot.

4. The robot according to claim 1, wherein
when the substrate is transferred by the hand, the teaching member is in a posture wherein the teaching member is overlapped with the manipulator at least partially in a plan view.

5. The robot according to claim 4, wherein
when the substrate is transferred by the hand, the teaching member maintains a posture wherein the teaching member is aligned with the most apical link of the manipulator in the plan view.

6. The robot according to claim 1, wherein
when teaching to the robot is performed by the teaching member, the hand is in a posture wherein the hand is overlapped with the manipulator at least partially in a plan view.

7. The robot according to claim 1, wherein
the hand is rotatably connected to a tip of the manipulator around the vertical axis, and
the teaching member is rotatably connected to the tip of the manipulator around an axis coaxially with the vertical axis around which the hand is rotatable.

8. A teaching method for a horizontally articulated robot that holds and transfers a substrate by a hand connected to a manipulator, wherein
teaching is performed using a teaching member connected to the manipulator, the teaching member being not used for transferring a substrate.
